(19) United States
(12) Patent Application Publication
(10) Pub. No.: US 2026/0255724 A1
(43) Pub. Date: Aug. 27, 2026

(54) HOT CARRIER SOLAR CELL

(71) Applicant: National Taiwan University, Taipei (TW)

(72) Inventors: Ching-Fuh Lin, Taipei (TW); Wei-Cheng Hsu, Taipei (TW)

(21) Appl. No.: 19/548,605

(22) Filed: Feb. 24, 2026

(30) Foreign Application Priority Data
Feb. 27, 2025 (TW) 114107396

(51) Int. Cl. H10F 77/70

(52) U.S. Cl. CPC H10F 77/70

(57) ABSTRACT

A hot carrier solar cell includes a semiconductor layer, a metal layer, a first electrode, and a second electrode. An upper surface of the semiconductor layer is flat or forms an inverted pyramid structure or microstructure array. A lower surface of the metal layer contacts an upper surface of the semiconductor layer. The first electrode contacts an upper surface of the metal layer. The period of the inverted pyramid structure array and morphology, thickness, deposition rate, particle size, particle spacing, annealing temperature, etc. of the metal layer each affects properties of the cells. By adjusting one or more parameters, the hot-carrier solar cell can absorb incident light with wavelengths greater than the wavelength corresponding to the bandgap of the semiconductor layer, thereby achieving a conversion efficiency of over 6%.

### CROSS REFERENCE TO RELATED APPLICATIONS

The entire contents of Taiwan Patent Application No. 114107396, filed on Feb. 27, 2025, from which this application claims priority, are expressly incorporated herein by reference.

### BACKGROUND OF THE INVENTION

### 1. Field of the Invention

This invention generally relates to hot carrier solar cells with improved conversion efficiency.

### 2. Description of Related Art

US patent application Pub. No. US2023402558A1, entitled “Hot Carrier Solar Cell and Tandem Solar Cell,” had disclosed a hot carrier solar cell including a semiconductor layer, a light-absorbing layer, a first electrode, and a second electrode. The light-absorbing layer can be a metal layer or a semiconductor layer. A lower surface of the light-absorbing layer contacts an upper surface of the semiconductor layer, the first electrode contacts an upper surface of the light-absorbing layer, and the second electrode contacts a lower surface of the semiconductor layer. Furthermore, a tandem solar cell is provided to include the hot carrier solar cell. In a preferred embodiment, for incident light with wavelengths greater than 1100 nm and a photovoltaic irradiance of 13.85 mW/cm², the conversion efficiency of the hot carrier solar cell reaches 3.3%.

### SUMMARY OF THE INVENTION

This summary is provided to introduce a selection of concepts in a simplified form that are further described below in the detailed description. This summary, and the foregoing background, is not intended to identify key aspects or essential aspects of the claimed subject matter.

Moreover, this summary is not intended for use as an aid in determining the scope of the claimed subject matter.

An objective of this invention is to further improve the conversion efficiency of hot-carrier solar cells.

In one aspect, a hot-carrier solar cell is provided with a semiconductor layer, a metal layer, a first electrode, and a second electrode. The metal layer includes a plurality of continuous or discontinuous metal nano-islands in contact with an upper surface of the semiconductor layer. The first electrode contacts an upper surface of the metal layer. The second electrode contacts a lower surface of the semiconductor layer. After being excited by incident photons, carriers in the metal layer form hot carriers that cross the interface between the metal layer and the semiconductor layer, thus generating a photocurrent. In particular, the hot-carrier solar cell can absorb incident light with wavelengths greater than the cutoff wavelength corresponding to the bandgap of the semiconductor layer, thereby achieving a conversion efficiency of over 6%.

In one embodiment, the metal layer further includes a plurality of metal particles above the plurality of metal nano-islands. In one embodiment, the plurality of metal particles have a predetermined morphology.

In one embodiment, the upper surface of the semiconductor layer has an inverted pyramid structure array.

In one embodiment, the upper surface of the semiconductor layer has a micro-structure array that confines light therein for resonance.

In one embodiment, the first electrode is a finger-shaped electrode or mesh-shaped electrode on planes between adjacent inverted pyramid structures of the inverted pyramid structure array.

In one embodiment, the average particle size of the plurality of metal particles is between 30 nm and 100 nm.

In one embodiment, the spacing between the plurality of metal particles is between 0.2 nm and 5 nm.

In one embodiment, a period of the inverted pyramid structure array is between 2 μm and 16 μm.

In one embodiment, a thickness of the metal layer is between 8 nm and 18 nm.

In one embodiment, the metal layer is formed by thermal evaporation, and the deposition rate of the thermal evaporation is between 0.6 Å/s and 1.2 Å/s.

In one embodiment, the metal layer is made of gold, silver, titanium, copper, chromium, or nickel.

In one embodiment, the absorption of the hot-carrier solar cell for incident light with a wavelength of 1300 nm reaches 70.44%.

In one embodiment, the hot-carrier solar cell is annealed at a temperature between 35° C. and 200° C.

In one embodiment, some patterns of the finger-shaped or mesh electrode are located above some inverted pyramid structures of the inverted pyramid structure array.

In another aspect of the present disclosure, a method of manufacturing a hot-carrier solar cell comprises: providing a semiconductor layer; depositing a plurality of nanoparticles on an upper surface of the semiconductor layer; depositing a plurality of continuous or discontinuous metal nano-islands between the plurality of nanoparticles; removing the plurality of nanoparticles, the plurality of metal nano-islands forming a metal layer; depositing a first electrode on an upper surface of the metal layer; and depositing a second electrode on a lower surface of the semiconductor layer.

In one embodiment, the method further comprises: annealing the metal layer to form a plurality of metal particles on the plurality of metal nano-islands, the plurality of metal nano-islands and the plurality of metal particles constituting the metal layer.

In one embodiment, before the step of depositing the plurality of nanoparticles, the method further comprises: depositing an oxide layer on an upper surface of the semiconductor layer; and etching the oxide layer and the semiconductor layer to give the upper surface of the semiconductor layer a roughened structure.

### BRIEF DESCRIPTION OF THE DRAWINGS

FIG. 1 shows simulated electric field distributions of an inventive IPS hot carrier solar cell for different wavelengths of incident light (1200 nm to 1500 nm) and different metal particle sizes (10 nm to 60 nm).

FIG. 2 shows an electric-field-versus-particle-size curve illustrating the relationship between the simulated maximum electric fields and metal particle sizes (10 nm to 60 nm), all data of which were obtained at an incident light wavelength of 1300 nm.

FIG. 3 shows simulated electric field distributions of an inventive IPS hot carrier solar cell with different metal particle spacings (0.3, 0.5, 1, 2, 4, 6, 8, 10 nm), in which the IPS hot carrier solar cell refers as a hot carrier solar cell including an inverted pyramid array formed on a semiconductor layer thereof, and the simulation is performed with a constant incident light wavelength of 1300 nm and a constant particle size of 40 nm.

FIG. 4 is a curve illustrating the relationship between the electric fields obtained in FIG. 3 and metal particle spacings.

FIG. 5 shows simulated maximum electric fields of inventive IPS hot carrier solar cells with different periods (4, 6, 8, 10, 12, 14 μm), in which the simulation is performed with a constant incident light wavelength of 1300 nm.

FIG. 6 shows simulated electric fields of an inventive IPS hot carrier solar cell for different incident light wavelengths (1200 nm, 1300 nm, 1400 nm, 1500 nm), in which the IPS hot carrier solar cell has a constant period of 12 μm.

FIG. 7A shows absorption versus wavelength curve illustrating the relationship between incident light wavelengths and light absorption (%) of planar hot carrier solar cell and IPS hot carrier solar cells with different IPS periods (6, 8, 10, 12, 14 μm).

FIG. 7B shows the relationship between the absorptions (%) and periods (6, 8, 10, 12, 14 μm) of IPS hot carrier solar cells, in which the absorptions (%) are obtained from FIG. 7A with a constant incident light wavelength of 1300 nm.

FIG. 8A shows J-V curves of inventive IPS hot-carrier solar cells with different IPS periods (6, 8, 10, 12, 14 μm) and a constant silver film thickness of 12 nm formed by a constant deposition rate of 0.4 Å/s, wherein all data are obtained without use of a silicon substrate as a filter.

FIG. 8B shows the relationships between cell efficiencies and IPS periods of IPS hot-carrier solar cells from FIG. 8A.

FIG. 9A shows J-V curves of inventive IPS hot-carrier solar cells with different IPS periods (6, 8, 10, 12, 14 μm) and a constant silver film thickness of 12 nm formed by a constant deposition rate of 0.4 Å/s, wherein all data are obtained with a silicon substrate used as a filter.

FIG. 9B shows the relationships between cell efficiencies and IPS periods of IPS hot-carrier solar cells from FIG. 9A.

FIGS. 10A, 10B, and 10C are respectively cross-sectional SEM images of silver metal layers with thicknesses of 16 nm, 17 nm, and 18 nm deposited on an inverted pyramid silicon surface at a fixed thermal evaporation rate of 0.8 Å/s.

FIG. 10D shows curves illustrating the relationship between wavelengths (400-1800 nm) and light absorption (%) of three solar cells of FIGS. 10A-10C.

FIG. 10E shows a curve illustrating the relationship between absorption (%) and the three solar cells of FIGS. 10A-10C at a wavelength of 1300 nm.

FIGS. 11A, 11B, and 11C are respectively cross-sectional SEM images of silver metal layers with a constant thickness of 17 nm deposited on an inverted pyramid silicon surface by different rates 0.6, 0.8, and 1.0 Å/s.

FIG. 11D shows curves illustrating the relationship between wavelengths (400-1800 nm) and light absorption (%) of three solar cells of FIGS. 11A-11C.

FIG. 11E shows a curve illustrating the relationship between absorption (%) and the three solar cells of FIGS. 11A-11C at a wavelength of 1300 nm.

FIGS. 12A, 12B, 12C, and 12D are cross-sectional SEM images of silver metal layers with a constant thickness of 17 nm deposited on an inverted pyramid silicon surface by a constant rate of 0.8 Å/s and then unannealed or annealed at a temperature of 50, 75, and 100° C. respectively.

FIG. 12E shows curves illustrating the relationship between wavelengths (400-1800 nm) and light absorption (%) of four solar cells of FIGS. 12A-12D.

FIG. 12F shows a curve illustrating the relationship between absorption (%) and the four solar cells of FIGS. 12A-12D at a wavelength of 1300 nm.

FIG. 13A is a top view showing an IPS (10 μm period) silicon solar cell (silver film thickness 17 nm and deposition rate 0.8 Å/s) being divided into 25 regions.

FIG. 13B shows the conversion efficiency of the 25 regions with a silicon substrate used as a filter.

FIG. 13C shows the current density-voltage curves of the 25 regions divided into four parts.

FIG. 14A is a top view showing another IPS (10 μm period) silicon solar cell (silver film thickness 17 nm and deposition rate 0.8 Å/s) being divided into 25 regions, where a mesh electrode is used.

FIG. 14B shows the conversion efficiency of the 25 regions with a silicon substrate used as a filter.

FIG. 15 is a line graph showing the relationship between metal particle size and light intensity enhancement factor for different metal particle spacings (1.5, 2, 3, 4 nm).

FIG. 16 shows a hot-carrier solar cell according to an embodiment of the present invention.

FIG. 17 shows a hot-carrier solar cell according to another embodiment of the present invention.

FIG. 18 shows a method for fabricating the metal layer of a hot-carrier solar cell according to another embodiment of the present invention.

### DETAILED DESCRIPTION OF THE PREFERRED EMBODIMENT

Embodiments of the invention are now described and illustrated in the accompanying drawings, instances of which are to be interpreted to be to scale in some implementations while in other implementations, for each instance, not. In certain aspects, use of like or the same reference designators in the drawings and description refers to the same, similar or analogous components and/or elements, while according to other implementations the same use should not.

According to certain implementations, use of directional terms, such as, top, bottom, left, right, up, down, over, above, below, beneath, rear, front, clockwise, and counterclockwise, are to be construed literally, while in other implementations the same use should not. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components.

In the applicant's previously filed US patent application (US2023402558A1) and previous research (Chang, Chung-Han. Master thesis (2022), “High Efficiency Metal/Silicon Junction Hot Carrier Solar Cells for Harvesting Infrared Spectrum”, Graduate Institute of Photonics and Optoelectronics College of Electrical Engineering and Computer Science, National Taiwan University), planar (silver/silicon) junction solar cells and inverted pyramid silver/silicon junction solar cells both are provided. In which, solar cells with inverted pyramid structure (IPS) array formed on the semiconductor surfaces thereof reveal better efficiencies than that of planar type of solar cells. In particular, a solar cell including an IPS array (hereinafter referred to as IPS solar cell.) with a period of 14 μm has a photoelectric conversion efficiency of 4.779% with a silicon substrate used to filter the incident light. The above patent application and all published documents discussed in this disclosure are fully incorporated by reference as if fully set forth herein.

The absorption spectrum showed that the absorption of the inverted pyramid solar cell at an incident light wavelength of 1300 nanometer is 1.5 times that of the planar solar cell.

In addition, Table 1 shows the photovoltaic characteristics of planar and IPS silver/silicon junction hot carrier solar cells, in which a silicon substrate is used to filter out incident light with wavelengths less than 1100 nanometers.

TABLE 1

| | | | shot circuit | | | | |
|---|---|---|---|---|---|---|---|
| | open-circuit | short-circuit | current | fill | short circuit | shunt | |
| solar | voltage, | current, | density, | factor | resistance, Rs | resistance, | cell |
| cell | Voc(V) | Isc(mA) | Jsc(mA/cm²) | (%) | (Ohm) | Rsh (Ohm) | eff.(%) |
| Planar | 0.4114 | 5.605 | 1.147 | 52.32 | 95.3065 | 10763.4541 | 1.782 |
| IPS | 0.429 | 6.52 | 1.33 | 61.02 | 52.3662 | 6684.8707 | 2.52 |

As shown in Table 1, for infrared light with wavelengths exceeding 1100 nm, the planar solar cell exhibits a conversion efficiency of 1.782%, while the IPS solar cell reaches 2.52%.

In some embodiments, IPS hot carrier solar cells are provided with the metal layer thickness controlled to 11, 12, and 13 nm, respectively (deposited by a constant rate of 0.4 Å/s). Photoelectric conversion efficiency of the IPS hot carrier solar cells were measured with or without using a silicon substrate to filter light with wavelengths less than 1100 nm. The incident light irradiance after passing through the silicon substrate was 13.85 mW/cm². With the silicon substrate filter, the conversion efficiency was 1.3% when the metal layer thickness was 11 nm. At a thickness of 12 nm, efficiency increased to 2.14%. At a thickness of 13 nm, the efficiency decreased to 1.591%. The data without the filter showed the same trend in conversion efficiency, with the highest efficiency observed at a thickness of 12 nm.

Based on the experimental results, geometric shapes of the semiconductor surface, thickness and deposition/evaporation rate of the metal layer, and the surface morphology of the metal layer, etc., indeed affect the conversion efficiency of the hot carrier solar cell.

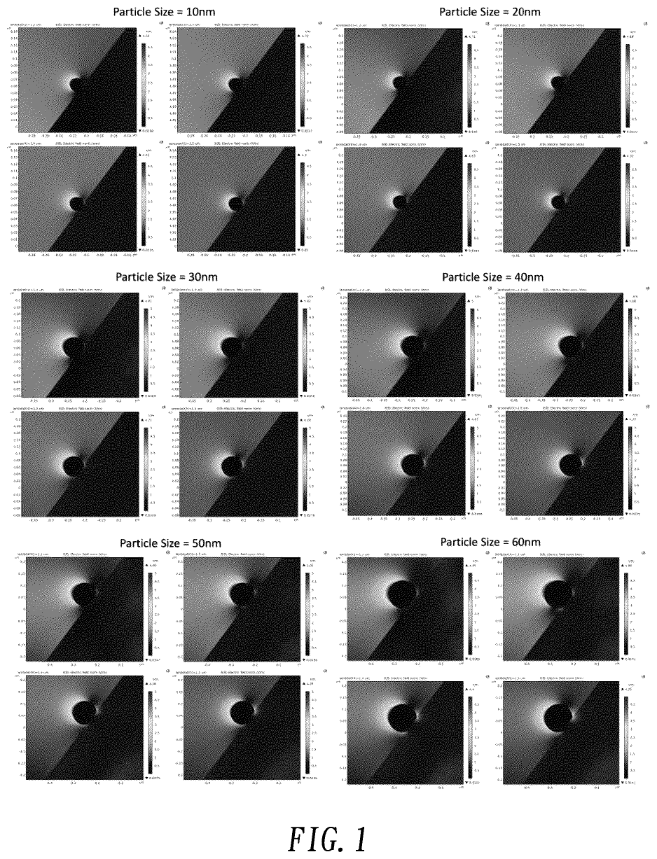

FIG. 1 shows simulated electric field distributions of inventive IPS hot carrier solar cells for different wavelengths of incident light (1200 nm to 1500 nm) and different metal particle sizes (10 nm to 60 nm). The semiconductor layer is a silicon substate, the metal layer is a silver layer, the inverted pyramid has a tilt angle of 53 degrees, and the incident light has an electric field of 1 V/m, incident vertically from top of the solar cell. The simulation results show that the maximum electric field for different metal particle sizes occurs at an incident light wavelength of 1300 nm.

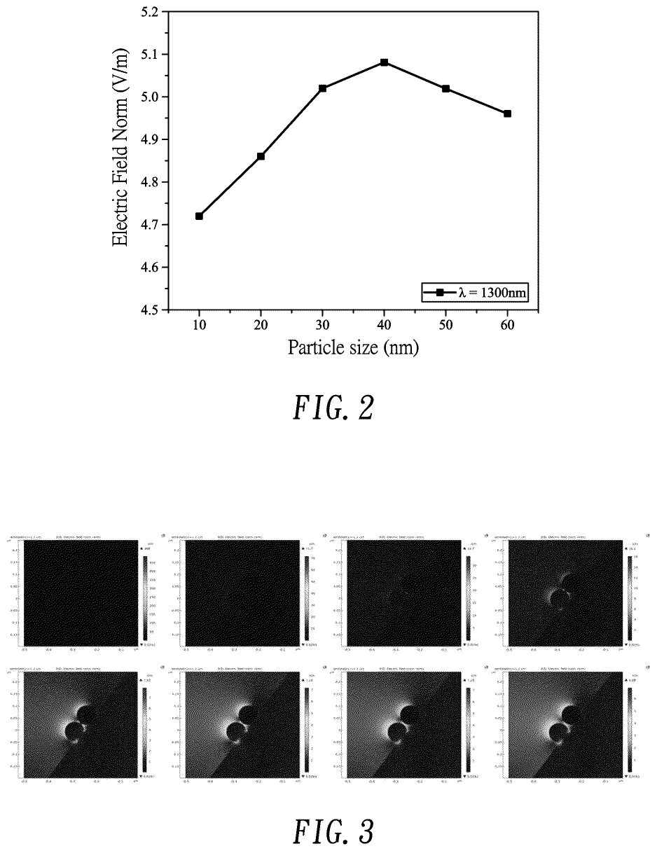

FIG. 2 shows an electric-field-versus-particle-size curve illustrating the relationship between the simulated maximum electric fields and metal particle sizes (10 nm to 60 nm), all data of which were obtained at an incident light wavelength of 1300 nm. As shown in FIG. 2, the maximum electric field increases continuously with increasing particle size, reaching a peak of 5.08 V/m at a particle size of 40 nm. As the particle size increases to 50 nm, the maximum electric field decreases to 5.02 V/m, and further decreases to 4.96 V/m at 60 nm.

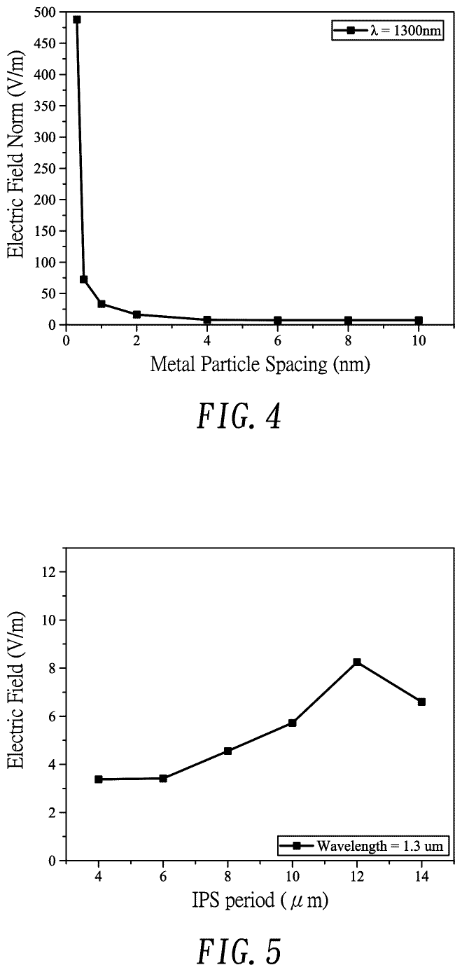

FIG. 3 shows simulated electric field distributions of an inventive IPS hot carrier solar cell with different metal particle spacings (0.3, 0.5, 1, 2, 4, 6, 8, 10 nm), in which the IPS hot carrier solar cell refers as a hot carrier solar cell including an inverted pyramid structure array formed on a semiconductor layer thereof, and the simulation is performed with a constant incident light wavelength of 1300 nm and a constant particle size of 40 nm. The simulation parameters are the same as those described in FIG. 1. FIG. 4 is a curve illustrating the relationship between the electric fields obtained in FIG. 3 and metal particle spacings. Initially, at a spacing of 0.3 nm, the electric field is as high as 488 V/m. As the spacing increases to 0.5 nm, the electric field decreases to 71.7 V/m. As the spacing increases to 1 nm, the electric field decreases to 33.7 V/m. Subsequently, as the spacing continued to increase, the rate of decrease in electric field gradually slowed down. The results show that the electric field strength is extremely sensitive to the spacing between the silver metal particles.

FIG. 5 shows simulated maximum electric fields of inventive IPS hot carrier solar cells with different periods (4, 6, 8, 10, 12, 14 μm), in which the simulation is performed with a constant incident light wavelength of 1300 nm. The simulation parameters are the same as those described in FIG. 1. The thickness of the silver metal film was 10 nm. As shown in FIG. 5, the maximum electric field strength of 8.23 V/m was observed as the period of the inverted pyramid array was 12 μm.

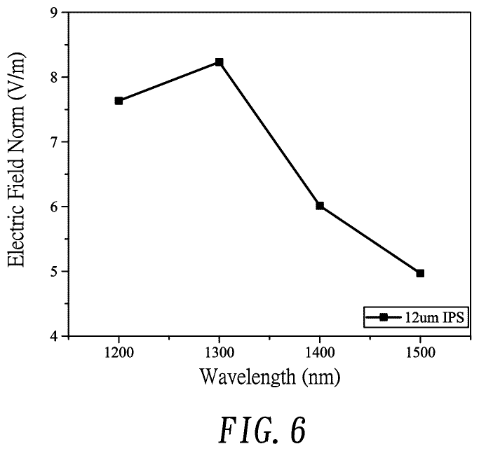

FIG. 6 shows simulated electric fields of an inventive IPS hot carrier solar cell for different incident light wavelengths (1200 nm, 1300 nm, 1400 nm, 1500 nm), in which the IPS hot carrier solar cell has a constant period of 12 μm. As shown in FIG. 6, the maximum electric field was observed at a wavelength of 1300 nm.

To be precise, the term “period” described in the present disclosure and FIG. 5 refers to the “aperture size” of the inverted pyramid structure array; in reality, the “period” is slightly larger than the “aperture size.” Furthermore, the electric field intensities were simulated for different ratios (0.9, 0.8, 0.7, 0.6, 0.5) of aperture size to IPS period. According to the simulation results, the maximum electric field did not show a significant trend with the ratio of aperture size to IPS period, and the difference in electric field intensity between different ratios was not significant.

Similar to previous studies, the measurement architecture of the hot carrier solar cell utilizes a 600 μm thick silicon wafer (N-type, Orientation: 1-0-0, resistance 2-7 Ω-cm, thickness 600-610 μm) as a filter to filter out incident light with wavelengths below 1100 nm, remaining only the longer wavelength portions of the AM1.5 G solar spectrum. Analysis using a spectrophotometer (JASCO V770 spectrometer) showed that this silicon wafer could not transmit light below 1100 nm, while its transmittance for light above 1100 nm was 55%. Measurements using a power meter showed that the intensity of the transmitted light was 13.85 mW/cm². Employing this measurement architecture and without using a filter, the cell conversion efficiency of a commercially available monocrystalline silicon p-n junction solar cell was 17.6%; with a filter, the conversion efficiency was only 0.26%.

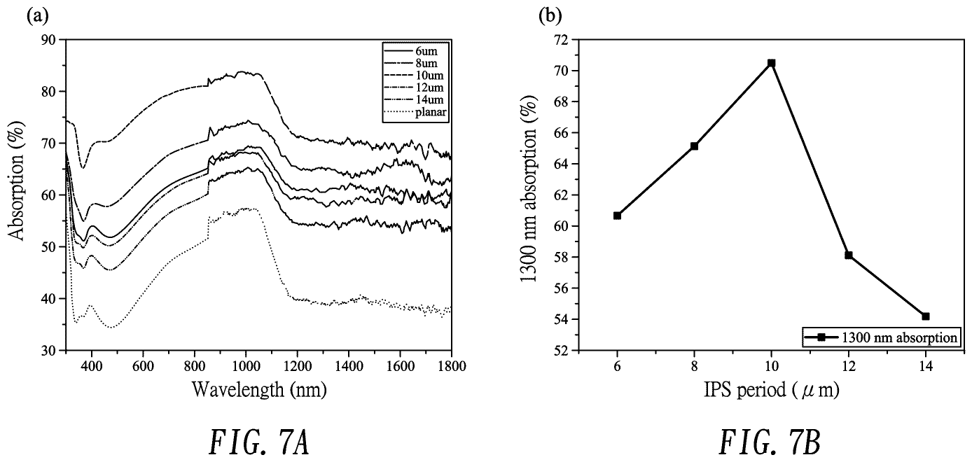

FIG. 7A shows absorption versus wavelength curve illustrating the relationship between incident light wavelengths and light absorption (%) of planar hot carrier solar cell and IPS hot carrier solar cells with different IPS periods (6, 8, 10, 12, 14 μm). FIG. 7B shows the relationship between the absorptions (%) and periods (6, 8, 10, 12, 14 μm) of IPS hot carrier solar cells, in which the absorptions (%) are obtained from FIG. 7A with a constant incident light wavelength of 1300 nm. As shown in FIG. 7B, the highest absorption is 70.44% for a period of 10 μm, followed by 68.11% for a period of 8 μm.

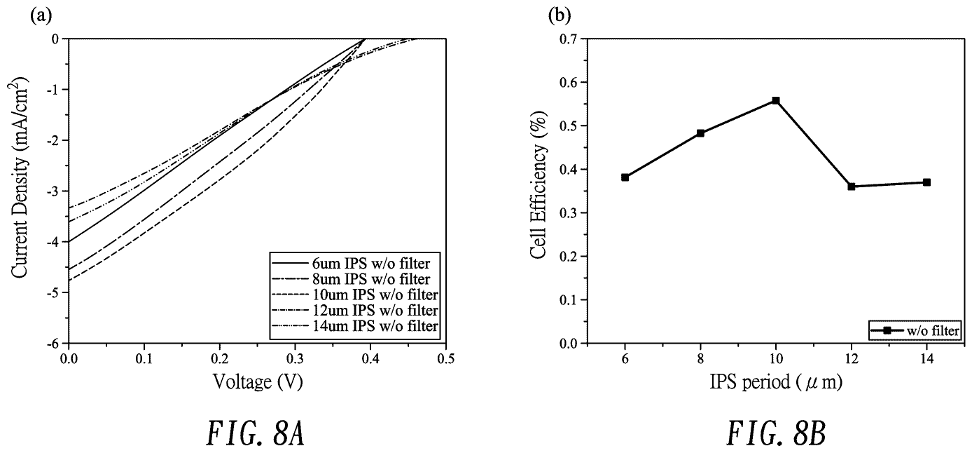

FIG. 8A shows J-V curves of inventive IPS hot-carrier solar cells with different IPS periods (6, 8, 10, 12, 14 μm) and a constant silver film thickness of 12 nm formed by a constant deposition rate of 0.4 Å/s, wherein all data are obtained without use of a silicon substrate as a filter. FIG. 8B shows the relationships between cell efficiencies and IPS periods of IPS hot-carrier solar cells from FIG. 8A. Relevant data are listed in Table 2.

TABLE 2

| | | | shot circuit | | | | |
|---|---|---|---|---|---|---|---|
| | open-circuit | short-circuit | current | fill | short circuit | shunt | |
| Period | voltage, | current, | density, | factor | resistance, Rs | resistance, | cell |
| (μm) | Voc(V) | Isc(mA) | Jsc(mA/cm²) | (%) | (Ohm) | Rsh (Ohm) | eff.(%) |
| 6 | 0.393 | 19.5 | 3.99 | 24.33 | 114.9367 | 101.5477 | 0.382 |
| 8 | 0.393 | 22.1 | 4.53 | 27.19 | 73.2927 | 108.6609 | 0.484 |
| 10 | 0.394 | 23.3 | 4.76 | 29.81 | 57.0943 | 111.3421 | 0.559 |
| 12 | 0.457 | 16.2 | 3.32 | 23.74 | 237.3843 | 156.7743 | 0.36 |
| 14 | 0.447 | 17.6 | 3.6 | 23.03 | 218.0937 | 135.7644 | 0.371 |

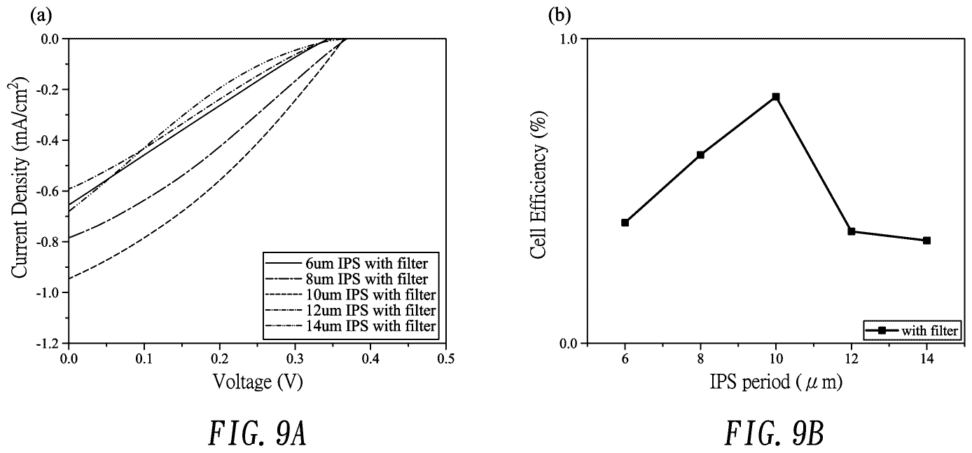

FIG. 9A shows J-V curves of inventive IPS hot-carrier solar cells with different IPS periods (6, 8, 10, 12, 14 μm) and a constant silver film thickness of 12 nm formed by a constant deposition rate of 0.4 Å/s, wherein all data are obtained with a silicon substrate used as a filter. FIG. 9B shows the relationships between cell efficiencies and IPS periods of IPS hot-carrier solar cells from FIG. 9A. Relevant data are listed in Table 3.

TABLE 3

| | | | shot circuit | | | | |
|---|---|---|---|---|---|---|---|
| | open-circuit | short-circuit | current | fill | short circuit | shunt | |
| Period | voltage, | current, | density, | factor | resistance, Rs | resistance, | cell |
| (μm) | Voc(V) | Isc(mA) | Jsc(mA/cm²) | (%) | (Ohm) | Rsh (Ohm) | eff.(%) |
| 6 | 0.344 | 3.2 | 0.655 | 24.36 | 627.8366 | 518.2933 | 0.396 |
| 8 | 0.368 | 3.84 | 0.786 | 29.61 | 420.4419 | 752.2051 | 0.619 |
| 10 | 0.366 | 4.64 | 0.948 | 32.26 | 248.5571 | 666.2869 | 0.808 |
| 12 | 0.3487 | 2.896 | 0.5925 | 24.52 | 811.6806 | 684.5504 | 0.3664 |
| 14 | 0.3625 | 3.336 | 0.6825 | 18.74 | 1725.581 | 407.5082 | 0.3353 |

As shown in Tables 2 and 3, the IPS silver/silicon junction solar cell with a period of 10 μm exhibits the best photoelectric conversion efficiency regardless of whether a filter is used.

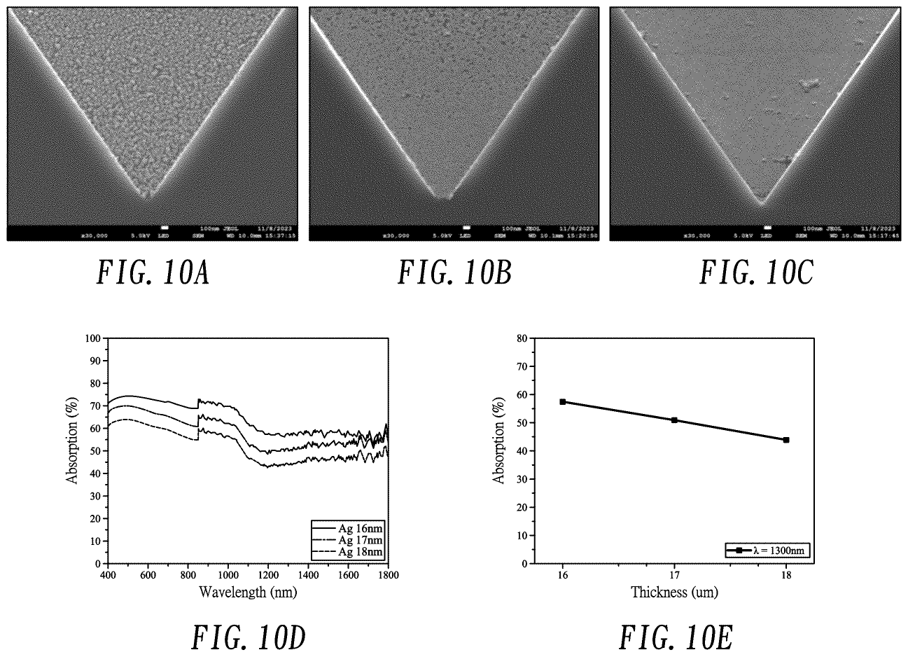

Furthermore, scanning electron microscopy revealed obvious gaps between metal islands in the metal layer, confirming the simulation results. This suggests that further increasing the thickness of the metal layer to make it more uniform and flatter may improve the cell's conductivity. The deposition rate and thickness of the metal film affect the surface morphology of the metal film. FIGS. 10A, 10B, and 10C are respectively cross-sectional SEM images of silver metal layers with thicknesses of 16 nm, 17 nm, and 18 nm deposited on an inverted pyramid silicon surface at a fixed thermal evaporation rate of 0.8 Å/s. FIG. 10D shows curves illustrating the relationship between wavelengths (400-1800 nm) and light absorption (%) of three solar cells of FIGS. 10A-10C. FIG. 10E shows a curve illustrating the relationship between absorption (%) and the three solar cells of FIGS. 10A-10C at a wavelength of 1300 nm.

As shown in FIGS. 10A-10C, the 16 nm thick silver film exhibits a distinct island-like structure, with each metal island independent and unconnected to the others. When the thickness increases to 17 nm, the metal islands begin to connect, forming a mesh structure, and the gaps narrow. When the thickness increases to 18 nm, the silver film exhibits a smooth shape, and the gaps completely disappear.

As shown in FIG. 10D, the absorption gradually decreases with increasing silver film thickness. As shown in FIG. 10E, for 1300 nm incident light, the absorption of the 16 nm thick metal film is 57.3%, decreasing to 50.8% at 17 nm, and further decreasing to 43.9% at 18 nm.

From the above results, the absorption is closely related to geographic features of the metal film. The island-like structure has extremely large gaps, allowing more wavelengths of light to resonate within the cavity, thus exhibiting optimal light-trapping capability on a macroscopic scale. However, the surface carrier transport capability of such structure is low due to the large gaps, resulting in poor conductivity. As the thickness of the metal film increases, the gaps gradually shrink, and the film uniformity improves, leading to increased light reflection and a gradual decrease in absorption. However, as the thickness increases, conductivity improves, thus requiring a balance between light absorption and conductivity.

Table 4 lists properties of IPS (10 μm period) silicon solar cells with different silver film thicknesses and without the use of a silicon substrate filter.

TABLE 4

| | | | shot circuit | | | | |
|---|---|---|---|---|---|---|---|
| | open-circuit | short-circuit | current | fill | short circuit | shunt | |
| silver film | voltage, | current, | density, | factor | resistance, Rs | resistance, | cell |
| thickness(nm) | Voc(V) | Isc(mA) | Jsc(mA/cm²) | (%) | (Ohm) | Rsh (Ohm) | eff.(%) |
| 16 | 0.5488 | 76.32 | 15.62 | 37.08 | 28.9094 | 293.6191 | 3.178 |
| 17 | 0.5871 | 73.17 | 14.97 | 39.9 | 20.6719 | 519.7683 | 3.507 |
| 18 | 0.46 | 17.21 | 84.14 | 30.77 | 18.3453 | 68.0293 | 2.437 |

As shown in Table 4, as the silver film thickness increased from 16 nm to 17 nm, the conversion efficiency of the solar cell increased from 3.178% to 3.507%. Because the increased uniformity of the silver film and the reduced gaps in the island structure significantly enhanced the carrier migration ability on the film surface, thereby improving the conversion efficiency. As the thickness continued to increase to 18 nm, the cell efficiency dropped sharply to 2.437%. This phenomenon stems from two competing mechanisms: on the one hand, the uniform film brings high conductivity; on the other hand, the reduced gaps lead to a decrease in light-harvesting and absorption, resulting in a decrease in efficiency.

Table 5 lists properties of IPS (10 μm period) silicon solar cells with different silver film thicknesses and with the use of a silicon substrate filter (infrared light with an irradiance of 13.85 mW/cm²). Similar to the results without a filter, the cell with a silver film thickness of 17 nm exhibited the highest conversion efficiency (5.11%).

TABLE 5

| | | | shot circuit | | | | |
|---|---|---|---|---|---|---|---|
| | open-circuit | short-circuit | current | fill | short circuit | shunt | |
| silver film | voltage, | current, | density, | factor | resistance, Rs | resistance, | cell |
| thickness(nm) | Voc(V) | Isc(mA) | Jsc(mA/cm²) | (%) | (Ohm) | Rsh (Ohm) | eff.(%) |
| 16 | 0.4271 | 9.968 | 2.039 | 59.62 | 48.9493 | 12963.1103 | 3.749 |
| 17 | 0.4244 | 15.11 | 3.091 | 53.95 | 40.5723 | 9042.7922 | 5.11 |
| 18 | 0.4017 | 1.374 | 6.714 | 61.55 | 60.1061 | 8895.6983 | 2.452 |

Based on the above experimental results, a (silver) metal layer thickness of 17 nm is determined. Then, metal layers were deposited at different evaporation rates to evaluate their impact on solar cells.

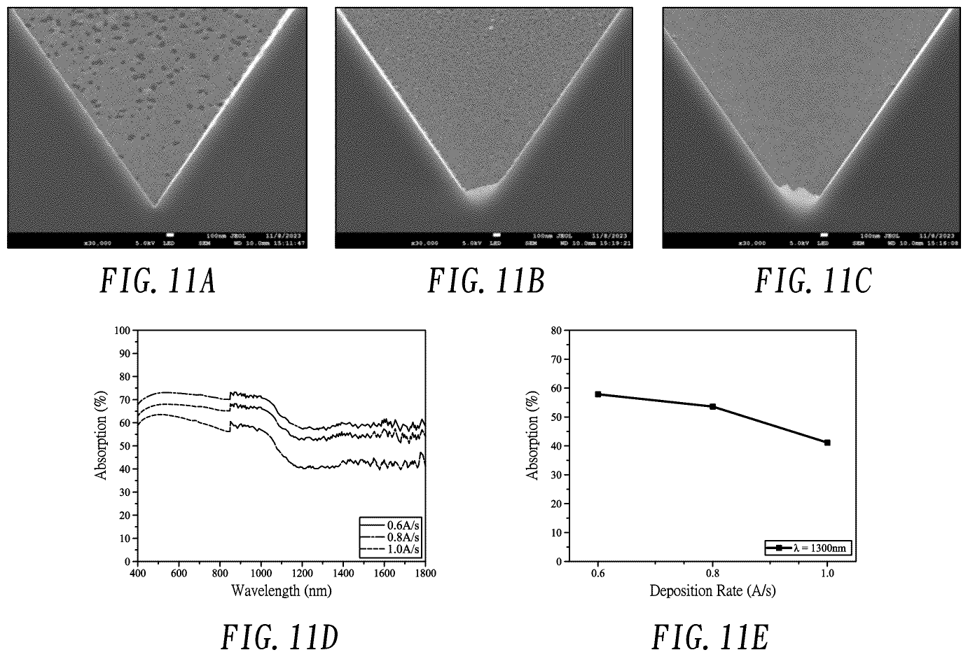

FIGS. 11A, 11B, and 11C are respectively cross-sectional SEM images of silver metal layers with a constant thickness of 17 nm deposited on an inverted pyramid silicon surface by different rates 0.6, 0.8, and 1.0 Å/s. FIG. 11D shows curves illustrating the relationship between wavelengths (400-1800 nm) and light absorption (%) of three solar cells of FIGS. 11A-11C. FIG. 11E shows a curve illustrating the relationship between absorption (%) and the three solar cells of FIGS. 11A-11C at a wavelength of 1300 nm.

As shown in FIGS. 11A-11C, as the deposition rate is 0.6 Å/s, the silver film exhibits obvious gaps; as the deposition rate increases to 0.8 Å/s, the gaps become very small; as the deposition rate further increases to 1.0 Å/s, most of the small pores disappear, resulting in a smooth and uniform silver film surface.

As shown in FIG. 11D, the absorption of the metal film decreases with increasing deposition rate. As shown in FIG. 11E, for 1300 nm incident light, the absorption decreases from 57.72% at deposition rate of 0.6 Å/s to 53.5% at 0.8 Å/s, and finally to 41.92% at 1.0 Å/s. This result is consistent with the discussion. The larger the gaps in the metal film and the rougher of the surface, the higher the probability of multiple reflections and absorptions of incident light on surface of the metal film, and therefore the higher the light absorption. On the contrary, metal films with higher uniformity have higher reflectivity, thus resulting in lower absorption. In some embodiments, a suitable deposition rate is between 0.7 Å/s and 0.9 Å/s.

Table 6 lists properties of IPS (10 μm period) silicon solar cells with a silver film thickness of 17 nm, wherein the silver films are deposited by different rates, and the properties are measured without the use of a silicon filter.

TABLE 6

| | | | shot circuit | | | | |
|---|---|---|---|---|---|---|---|
| | open-circuit | short-circuit | current | fill | short circuit | shunt | |
| deposition | voltage, | current, | density, | factor | resistance, | resistance, | cell |
| rate (Å/s) | Voc(V) | Isc(mA) | Jsc(mA/cm²) | (%) | Rs (Ohm) | Rsh (Ohm) | eff.(%) |
| 0.6 | 0.4453 | 16.81 | 82.16 | 30.67 | 25.2754 | 59.2072 | 2.296 |
| 0.8 | 0.5871 | 14.97 | 73.17 | 39.9 | 20.6719 | 519.7683 | 3.507 |
| 1 | 0.4561 | 17.15 | 83.84 | 30.74 | 19.3143 | 64.4133 | 2.405 |

As shown in Table 6, the solar cell efficiency is 2.296% for a deposition rate of 0.6 Å/s, and the efficiency increases significantly to 3.507% for the deposition rate of 0.8 Å/s. As the deposition rate increases to 1.0 Å/s, efficiency decreases to 2.405%. The disappearance of gaps may prevent the incident light from resonating on the metal film surface, thereby reducing the light absorption and the photoelectric conversion performance.

Table 7 lists properties of IPS (10 μm period) silicon solar cells with a silver film thickness of 17 nm, wherein the silver films are deposited by different rates, and the properties are measured with the use of a silicon filter (irradiance of 13.85 mW/cm²).

TABLE 7

| | | | shot circuit | | | | |
|---|---|---|---|---|---|---|---|
| | open-circuit | short-circuit | current | fill | short circuit | shunt | |
| deposition | voltage, | current, | density, | factor | resistance, | resistance, | cell |
| rate (Å/s) | Voc(V) | Isc(mA) | Jsc(mA/cm²) | (%) | Rs (Ohm) | Rsh (Ohm) | eff.(%) |
| 0.6 | 0.4054 | 2.085 | 10.19 | 58.73 | 46.0543 | 44992.767 | 3.584 |
| 0.8 | 0.4244 | 3.091 | 15.11 | 53.95 | 40.5723 | 9042.7922 | 5.11 |
| 1 | 0.4482 | 1.299 | 6.348 | 63.6 | 61.2672 | 6599.0734 | 2.672 |

As shown in Table 7, the solar cell with a deposition rate of 0.8 Å/s exhibits the highest conversion efficiency (5.11%) with a filter, consistent with the results without a filter.

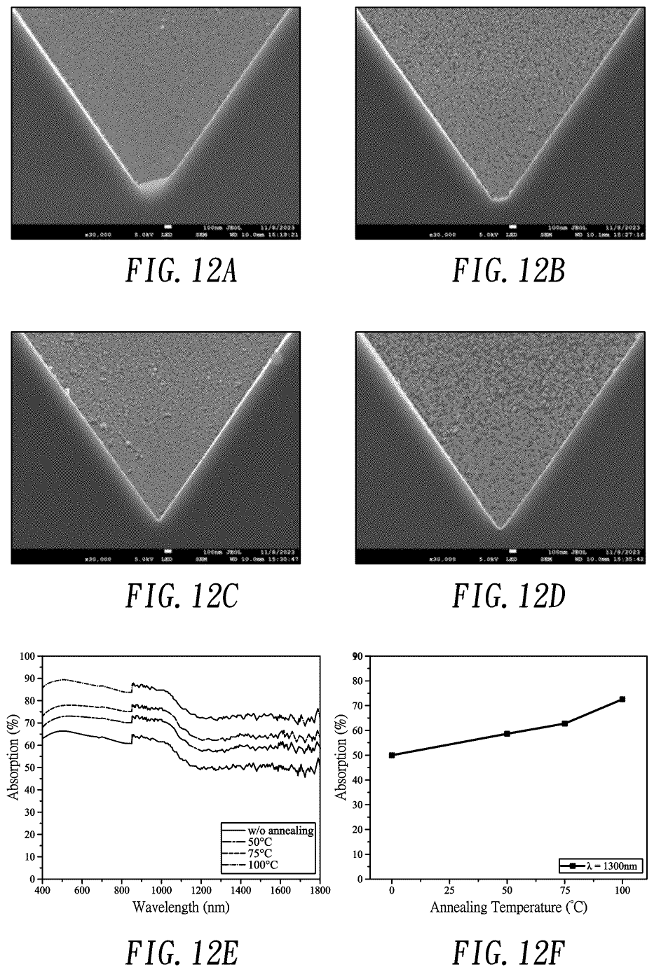

FIGS. 12A, 12B, 12C, and 12D are cross-sectional SEM images of silver metal layers with a constant thickness of 17 nm deposited on an inverted pyramid silicon surface by a constant rate of 0.8 Å/s and then unannealed or annealed at a temperature of 50, 75, and 100° C. respectively. FIG. 12E shows curves illustrating the relationship between wavelengths (400-1800 nm) and light absorption (%) of four solar cells of FIGS. 12A-12D. FIG. 12F shows a curve illustrating the relationship between absorption (%) and the four solar cells of FIGS. 12A-12D at a wavelength of 1300 nm.

As shown in FIG. 12A, before annealing, the silver film exhibits a relatively dense network structure. Referring to FIG. 12B, after annealing at 50° C., silver nanoparticles migrate and merge, forming island-like structures. These islands gradually become disconnected, and the size and density of the metal islands are nearly uniform. Referring to FIG. 12C, as the annealing temperature rises to 75° C., aggregation of the metal particles becomes increasingly apparent. Referring to FIG. 12D, at 100° C., the film exhibits even greater aggregation, with significantly larger grains and correspondingly increased gaps between the grains.

As shown in FIG. 12E, the absorption of the solar cell increases with increasing annealing temperature. As shown in FIG. 12F, for 1300 nm incident light, the absorption of the unannealed cell is 50.11%. After annealing at 50° C., the film aggregates to form island-like structures. The gaps between these islands act as resonant cavities for the incident light, increasing the absorption to 58.59%. As the annealing temperature rises to 75° C., the absorption increases to 62.78%. As the temperature reaches 100° C., the metal film has a larger resonant cavity and a significantly improved roughness, and the absorption further increases to 72.37%.

Table 8 lists properties of IPS (10 μm period) silicon solar cells with a silver film thickness of 17 nm, wherein the silver films are deposited by the same rate of 0.8 Å/s and then unannealed or annealed at a temperature of 50, 75, and 100° C. respectively, and the properties are measured without the use of a silicon substrate filter.

TABLE 8

| | | | shot circuit | | | | |
|---|---|---|---|---|---|---|---|
| | open-circuit | short-circuit | current | fill | short circuit | shunt | |
| Annealing | voltage, | current, | density, | factor | resistance, | resistance, | cell |
| temp. (° C.) | Voc(V) | Isc(mA) | Jsc(mA/cm2) | (%) | Rs (Ohm) | Rsh (Ohm) | eff.(%) |
| w/o | 0.5871 | 73.17 | 14.97 | 39.9 | 20.6719 | 519.7683 | 3.507 |
| 50 | 0.5833 | 15.65 | 76.48 | 39.1 | 17.5441 | 394.3186 | 3.691 |
| 75 | 0.5787 | 14.75 | 72.1 | 38.3 | 19.9724 | 218.5851 | 3.27 |
| 100 | 0.4729 | 17.1 | 83.56 | 30.72 | 23.7631 | 67.0375 | 2.484 |

As shown in Table 8, the efficiency of the IPS (10 μm period) solar cell is 3.507% before annealing. After annealing at 50° C., the silver film exhibits an island-like structure with numerous tiny gaps, which facilitates internal resonance and enhances light absorption. Simultaneously, these gaps also induce surface plasma resonance, thus increasing the photocurrent and raising the conversion efficiency to 3.691%. However, as the temperature further increases to 75° C., the efficiency gradually decreases to 3.27%. As the temperature further increases to 100° C., efficiency drops sharply to 2.484%. Accordingly, in some embodiments, an annealing temperature is determined between 35° C. and 65° C.

Table 9 lists properties of IPS (10 μm period) silicon solar cells with a silver film thickness of 17 nm, wherein the silver films are deposited by the same rate of 0.8 Å/s and then unannealed or annealed at a temperature of 50, 75, and 100° C. respectively, and the properties are measured without the use of a silicon substrate filter (irradiance of 13.85 mW/cm²).

TABLE 9

| | | | shot circuit | | | | |
|---|---|---|---|---|---|---|---|
| | open-circuit | short-circuit | current | fill | short circuit | shunt | |
| Annealing | voltage, | current, | density, | factor | resistance, | resistance, | cell |
| temp. (° C.) | Voc(V) | Isc(mA) | Jsc(mA/cm2) | (%) | Rs (Ohm) | Rsh (Ohm) | eff.(%) |
| w/o | 0.4244 | 3.091 | 15.11 | 53.95 | 40.5723 | 9042.7922 | 5.11 |
| 50 | 0.4433 | 3.084 | 15.07 | 54.73 | 39.9573 | 65365.877 | 5.402 |
| 75 | 0.4083 | 2.26 | 11.05 | 57.48 | 47.4344 | 13880.4365 | 3.831 |
| 100 | 0.4494 | 1.165 | 5.694 | 56.79 | 74.2697 | 3955.4767 | 2.146 |

As shown in Table 9, with the filter, the solar cell annealed at 50° C. for 10 minutes exhibited the highest conversion efficiency (5.402%).

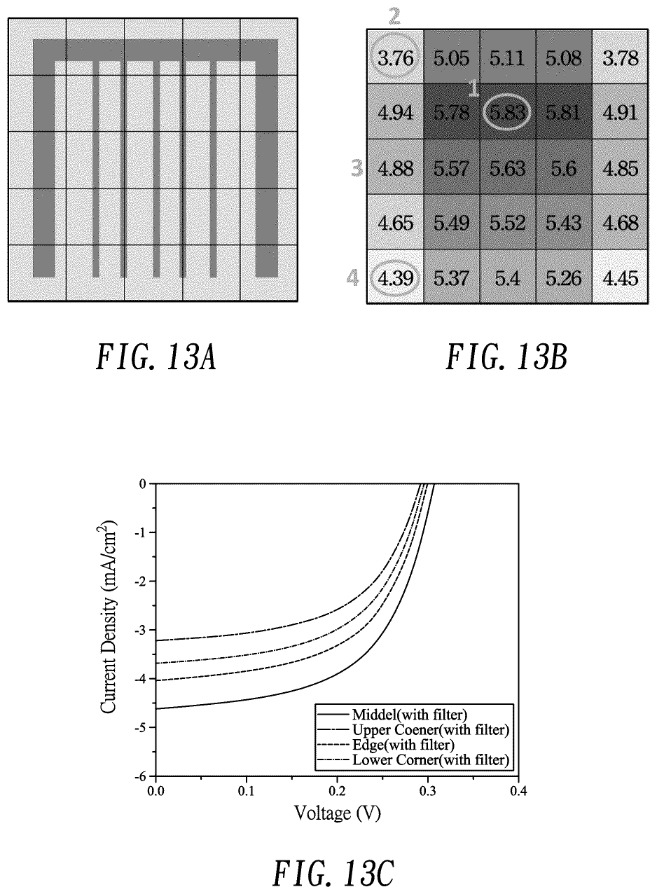

FIG. 13A is a top view showing an IPS (10 μm period) silicon solar cell (silver film thickness 17 nm and deposition rate 0.8 Å/s) being divided into 25 regions. FIG. 13B shows the conversion efficiency of the 25 regions with a silicon substrate used as a filter. FIG. 13C shows the current density-voltage curves of the 25 regions divided into four parts. Table 10 lists properties of the four portions (with filter). Table 11 lists properties of the four portions (without filter).

TABLE 10

| | | | shot circuit | | | shunt | |
|---|---|---|---|---|---|---|---|
| | open-circuit | short-circuit | current | fill | short circuit | resistance, | |
| | voltage, | current, | density, | factor | resistance, | Rsh | cell |
| portion | Voc(V) | Isc(mA) | Jsc(mA/cm²) | (%) | Rs (Ohm) | (Ohm) | eff.(%) |
| 1 | 0.307 | 1.15 | 4.61 | 56.98 | 10.5671 | 706.6424 | 5.83 |
| (Middle) | | | | | | | |
| 2 (Upper | 0.293 | 0.805 | 3.22 | 55.37 | 13.3586 | 808.3216 | 3.76 |
| Corner) | | | | | | | |
| 3 (Edge) | 0.3 | 1.01 | 4.03 | 56.01 | 12.5647 | 650.9114 | 4.88 |
| 4 (Lower | 0.296 | 0.922 | 3.69 | 55.54 | 12.7051 | 727.6525 | 4.39 |
| Corner) | | | | | | | |

TABLE 11

| | | | shot circuit | | | shunt | |
|---|---|---|---|---|---|---|---|
| | open-circuit | short-circuit | current | fill | short circuit | resistance, | |
| | voltage, | current, | density, | factor | resistance, | Rsh | cell |
| portion | Voc(V) | Isc(mA) | Jsc(mA/cm²) | (%) | Rs (Ohm) | (Ohm) | eff.(%) |
| 1 | 0.367 | 4.59 | 18.4 | 59.37 | 3.7014 | 390.7209 | 4 |
| (Middle) | | | | | | | |
| 2 (Upper | 0.346 | 3.06 | 12.3 | 55.03 | 6.4185 | 292.6705 | 2.33 |
| Corner) | | | | | | | |
| 3 (Edge) | 0.359 | 4.62 | 18.5 | 52.36 | 4.3096 | 210.6997 | 3.48 |
| 4 (Lower | 0.347 | 3.74 | 15 | 54.65 | 5.5517 | 397.8322 | 2.83 |
| Corner) | | | | | | | |

As shown in Tables 10 and 11, regardless of whether a silicon substrate filter is used, the photoelectric conversion efficiency is higher in the middle portion where a large area of which is not covered by the finger electrode compared to other portions. The conversion efficiency of the four portions, from highest to lowest, is: 1 (Middle)>3 (Edge)>4 (Lower Corner)>2 (Upper Corner).

Furthermore, within the middle portion, the difference in photoelectric conversion efficiency between regions is small, demonstrating the uniformity of the evaporated silver metal film. Additionally, the overall solar cell conversion efficiency is 3.507% without the filter and 5.11% with filter, in which the highest efficiency in individual regions is 4% without the filter and 5.83% with the filter. The highest efficiency in individual regions is greater than the overall conversion efficiency of the entire solar cell.

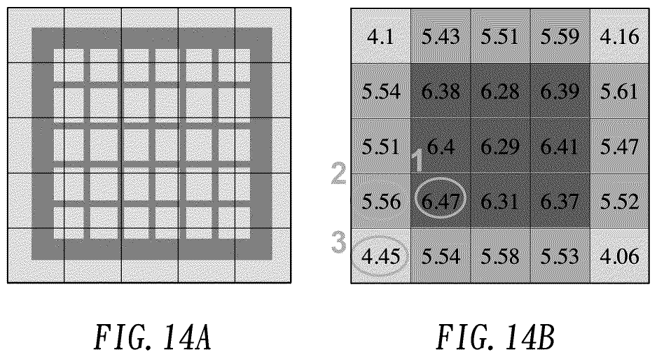

FIG. 14A is a top view showing another IPS (10 μm period) silicon solar cell (silver film thickness 17 nm and deposition rate 0.8 Å/s) being divided into 25 regions, where a mesh electrode is used. FIG. 14B shows the conversion efficiency of the 25 regions of the 2.5 cm×2.5 cm solar cell with a silicon substrate used as a filter. In addition, three IPS (10 μm period) silicon solar cells with silver film thicknesses of 16 nm, 17 nm, and 18 nm, and finger electrodes, were also fabricated by the same process for comparison.

Table 12 lists properties of the IPS silicon solar cell with the mesh electrode and the three silicon solar cells with finger electrodes (with silicon substrate filter). As shown in Table 12, the solar cell with mesh electrode has a higher efficiency of 6.083 than cells with finger electrodes.

TABLE 12

| | open- | shot circuit | | |
|---|---|---|---|---|
| | circuit | current | fill | |
| silicon | voltage, | density, | factor | cell eff. |
| solar cell | Voc(V) | Jsc(mA/cm²) | (%) | (%) |
| 16(finger | 0.4139 | 2.31 | 52.89 | 3.652 |
| electrode) | | | | |
| 17(finger | 0.4244 | 3.091 | 53.95 | 5.11 |
| electrode) | | | | |
| 18(finger | 0.4264 | 1.898 | 51.38 | 3.003 |
| electrode) | | | | |
| mesh electrode | 0.4502 | 3.204 | 58.41 | 6.083 |

Some experiments, e.g., the experiments shown in FIGS. 2 to 5, the center wavelength of the incident light is 1300 nm. Experiments were also performed with incident light at a center wavelength of 1500 nm. Table 13 lists for incident light at 1500 nm, simulated maximum electric fields and properties of IPS solar cells with metal (silver) particle spacing of 1.5 nm and metal particle diameters ranging from 10 nm to 100 nm. The incident light intensity is set to 20 mW/cm², the incident electric field to 274.6 V/m, and the contact angle to 90 degrees. The formula for converting light intensity to electric field is: P(mw/cm²)=[E²(V/m)]²/(10×Z₀)=[E²(V/m)]²/3770.

TABLE 13

| | Max. | Electric Field | Light intensity |
|---|---|---|---|
| Metal particle | Electric | Enhancement | Enhancement |
| diameter (nm) | Field V/m | Factor | Factor |
| 100 | 19503.5 | 71.02513 | 5044.914 |
| 90 | 20512.8 | 74.70066 | 5580.57 |
| 80 | 22960.5 | 83.61435 | 6991.838 |
| 70 | 26091.7 | 95.01712 | 9028.87 |
| 60 | 37191 | 135.437 | 18344.44 |
| 57.5 | 43780.1 | 159.4323 | 25420.39 |
| 55 | 55001.3 | 200.2961 | 40121.26 |
| 52.5 | 78812.6 | 287.0087 | 82379.65 |
| 50 | 97387.1 | 354.6508 | 125785.8 |
| 47.5 | 75037.2 | 273.26 | 74676.15 |
| 45 | 45367.4 | 165.2127 | 27297.1 |
| 42.5 | 28538.3 | 103.9268 | 10801.52 |
| 40 | 20054.2 | 73.03059 | 5333.832 |
| 30 | 7140.56 | 26.0035 | 676.2281 |
| 20 | 2863.19 | 10.42677 | 108.7249 |
| 10 | 1237.47 | 4.506446 | 20.30944 |

With the same conditions as Table 13, Table 14 lists for incident light at 1500 nm, simulated maximum electric fields and properties of IPS solar cells with metal (silver) particle spacing of 2 nm and metal particle diameters ranging from 10 nm to 100 nm.

TABLE 14

| | Max. | Electric Field | Light intensity |
|---|---|---|---|
| Metal particle | Electric | Enhancement | Enhancement |
| diameter (nm) | Field V/m | Factor | Factor |
| 100 | 18997 | 69.18063 | 4786.287 |
| 90 | 19981 | 72.76402 | 5294.965 |
| 80 | 21106.1 | 76.86125 | 5908.056 |
| 70 | 31523 | 114.7961 | 13179.04 |
| 65 | 40662.5 | 148.079 | 21928.9 |
| 62.5 | 48497.1 | 176.61 | 31193.22 |
| 60 | 62712.7 | 228.3784 | 52160.25 |
| 55 | 54664.8 | 199.0706 | 39631.84 |
| 50 | 30183.1 | 109.9166 | 12082.49 |
| 40 | 10164.3 | 37.01493 | 1370.199 |
| 30 | 4414.23 | 16.07513 | 258.4274 |
| 20 | 2142.39 | 7.801857 | 60.87314 |
| 10 | 1208.98 | 4.402695 | 19.38505 |

With the same conditions as Table 13, Table 15 lists for incident light at 1500 nm, simulated maximum electric fields and properties of IPS solar cells with metal (silver) particle spacing of 3 nm and metal particle diameters ranging from 10 nm to 100 nm.

TABLE 15

| Metal particle | Max. Electric | Electric Field | Light intensity |
|---|---|---|---|
| diameter (nm) | Field V/m | Enhancement Factor | Enhancement Factor |
| 100 | 17741 | 64.6067 | 4174.311 |
| 90 | 20381.2 | 74.22141 | 5509.195 |
| 80 | 26931.1 | 98.07393 | 9619.153 |
| 75 | 35583.5 | 129.583 | 16792.91 |
| 70 | 42798.4 | 155.8572 | 24293.14 |
| 65 | 34606.1 | 126.0237 | 15883.05 |
| 60 | 23225 | 84.57757 | 7153.854 |
| 55 | 13595.6 | 49.51056 | 2451.463 |
| 50 | 9624.45 | 35.04898 | 1228.515 |
| 40 | 5193.75 | 18.91387 | 357.7591 |
| 30 | 2733.56 | 9.954698 | 99.10279 |
| 20 | 1445.21 | 5.262964 | 27.70069 |
| 10 | 1257.21 | 4.578332 | 20.96256 |

With the same conditions as Table 13, Table 16 lists for incident light at 1500 nm, simulated maximum electric fields and properties of IPS solar cells with metal (silver) particle spacing of 4 nm and metal particle diameters ranging from 10 nm to 100 nm.

TABLE 16

| Metal particle | Max. Electric | Electric Field | Light intensity |
|---|---|---|---|
| diameter (nm) | Field V/m | Enhancement Factor | Enhancement Factor |
| 100 | 16622 | 60.53168 | 3664.335 |
| 90 | 19888.6 | 72.42753 | 5246.106 |
| 80 | 26807.7 | 97.62454 | 9531.204 |
| 70 | 20736.6 | 75.51566 | 5703.005 |
| 60 | 11043.9 | 40.21814 | 1617.609 |
| 50 | 5733.55 | 20.87964 | 435.9893 |
| 40 | 3417.01 | 12.44359 | 154.8535 |
| 30 | 1983.27 | 7.222396 | 52.16658 |
| 20 | 1328.88 | 4.83933 | 23.42072 |
| 10 | 1236.55 | 4.503095 | 20.27926 |

Table 17 lists properties of IPS solar cells with different metal particle spacings (1.5, 2, 3, 4 nm) and constant metal particle diameter of 50 nm. The data are adapter from Tables 14-16.

TABLE 17

| Metal particle | Max. Electric | Electric Field | Light intensity |
|---|---|---|---|
| diameter (nm) | Field V/m | Enhancement Factor | Enhancement Factor |
| 1.5 | 97387.1 | 354.6508 | 125785.8 |
| 2 | 30183.1 | 109.9166 | 12082.49 |
| 3 | 9624.45 | 35.04898 | 1228.515 |
| 4 | 5733.55 | 20.87964 | 435.9893 |

As shown in Tables 13 to 16, for metal particle spacing of 1.5 nm, the maximum electric field and light intensity enhancement factor are achieved as the particle size is 50 nm. For metal particle spacing of 2 nm, the maximum electric field and light intensity enhancement factor are achieved as the particle size is 60 nm. For metal particle spacing of 3 nm, the maximum electric field and light intensity enhancement factor are achieved as the particle size is 70 nm. For metal particle spacing of 4 nm, the maximum electric field and light intensity enhancement factor are achieved as the particle size is 80 nm.

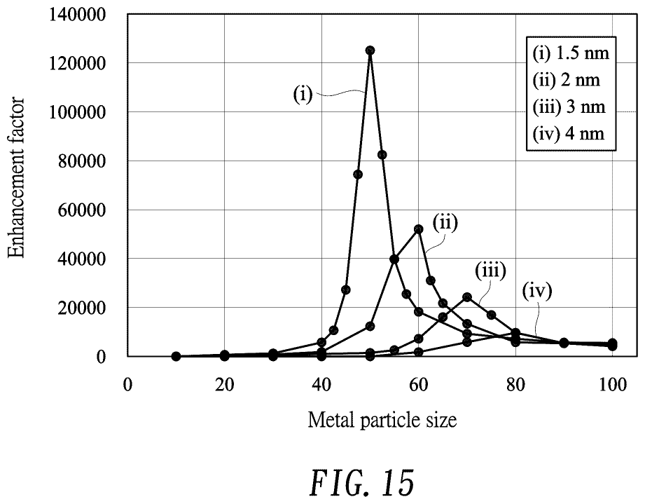

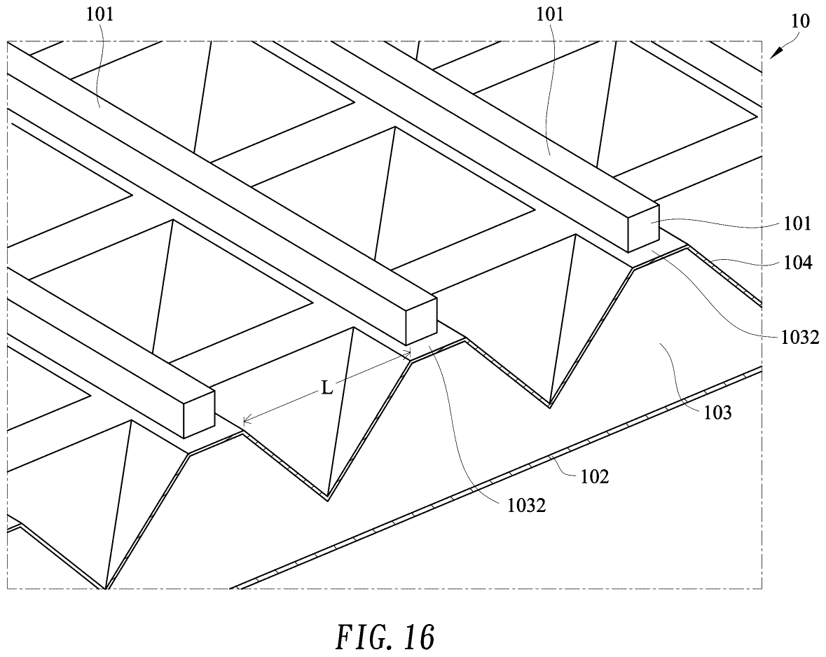

FIG. 15 is a line graph, based on the data in Tables 12 to 15, showing the relationship between metal particle size and light intensity enhancement factor for different metal particle spacings (1.5, 2, 3, 4 nm). As shown in FIG. 15, the light intensity enhancement factor can reach 125,780 times, far exceeding the enhancement achievable by traditional solar concentrating technology.

Based on the experimental results, FIG. 16 shows a hot-carrier solar cell in accordance with an embodiment of the present invention. The hot-carrier solar cell includes a semiconductor layer 103, a metal layer 104, a first electrode 101, and a second electrode 102. The semiconductor layer 103 is preferably, but is not limited to, a silicon substrate. The surface of the semiconductor layer 103 can be planar, or as shown in FIG. 16, an inverted pyramid structure (IPS) array can be formed on the surface of the semiconductor layer 103 by a suitable process, such as, but not limited to, dry etching or wet etching performed to the semiconductor layer 103. The metal layer 104 (inverted pyramid-shaped) is conformally formed on the inverted pyramid array of the semiconductor layer 103. A lower surface of the metal layer 104 forms a Schottky contact with an upper surface of the inverted pyramid array. The first electrode 101 is in contact with the upper surface of the metal layer 104. The second electrode 102 forms an ohmic contact with the lower (back) surface of the semiconductor layer 103. After being excited by incident photons, carriers in the metal layer 104 form hot carriers that cross the interface between the metal layer 104 and the semiconductor layer 103, thus generating a photocurrent. A finger-shaped first electrode 101 may be deposited on a plane 1032 between adjacent pyramid structures. It is not necessary to have a first electrode 101 on every plane 1032. Unless otherwise specified, the term “period” in this disclosure refers to the “aperture size (L)” of the IPS array. The first electrode 101 and the second electrode 102 can be made of aluminum or other metals. In some embodiments, the metal layer 104 is composed of a plurality of metal particles, the average particle size of which is between 30 nm and 100 nm. In some embodiments, the metal layer 104 is composed of a plurality of metal particles, with the spacing between 0.2 nm and 5 nm.

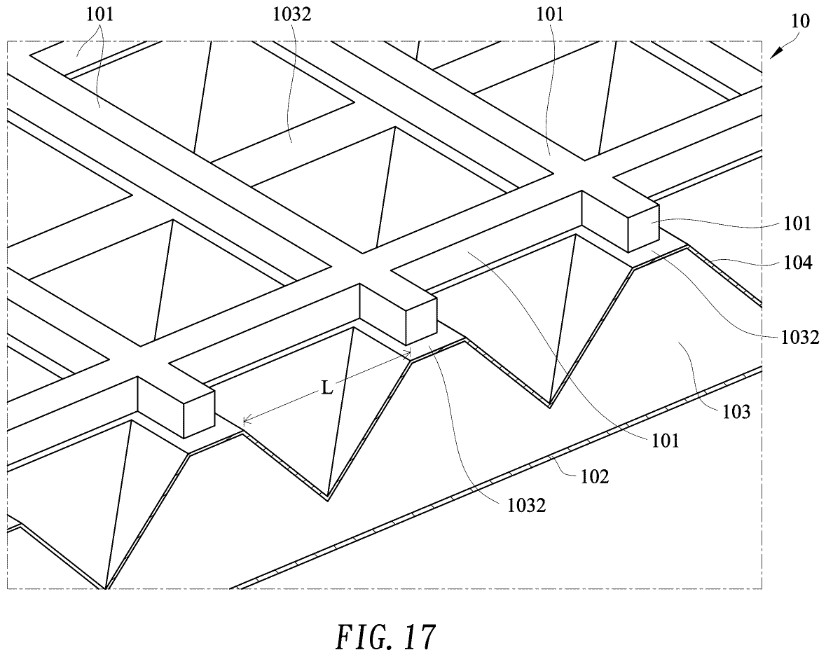

FIG. 17 shows a hot carrier solar cell 10 according to another embodiment of the present invention. The hot carrier solar cell 10 differs from that of FIG. 16 in that the first electrode 101 is a mesh electrode, preferably formed on planes 1032 between adjacent pyramid structures. As shown in FIG. 16, preferably, the planes 1032 are connected in a mesh pattern. It is not necessary to have a pattern of the first electrode 101 on every plane 1032 in both the longitudinal and transverse directions. As shown in FIGS. 13, 14, and 16, in some embodiments, some patterns of the finger or mesh electrode may be located above some inverted pyramid structures.

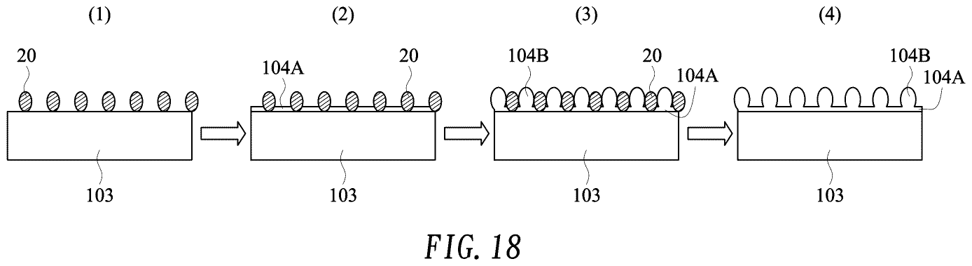

Experimental results have demonstrated that the particle size and spacing of the metal layer both affect characteristics of the hot carrier solar cell. FIG. 18 shows a method for fabricating the metal layer of a hot carrier solar cell according to another embodiment of the present invention. Referring to step (1), nanoparticles 20 with a predetermined morphology are deposited on the surface of a semiconductor layer (e.g., silicon) by a suitable process, such as spin coating. The nanoparticles 20 can be non-metallic or metallic, such as SiO₂, TiO₂, or Ag. Next, in step (2), a plurality of metal nano islands 104A are deposited between the nanoparticles 20 by a suitable method, such as thermal evaporation. The plurality of metal nano islands 104A can be continuous (connected) or discontinuous (not connected). In step (3), annealing can be performed to further change the morphology of the metal nano islands 104A, for example, forming metal particles 104B on their surface. In one embodiment, the annealing described in step (3) may not be required. In Step (4), removes the nanoparticles deposited in step 1 by an appropriate method, such as etching. Compared to directly depositing metal on the surface of a semiconductor layer (e.g., silicon), the method of FIG. 18 allows for precise control of the surface morphology, including e.g., the size, shape, and/or spacing of the metal nano islands 104A and metal particles 104B of the metal layer. The fabrication method of FIG. 18 can be applied to planar hot-carrier solar cells or IPS hot-carrier solar cells described in this disclosure.

Referring to FIG. 18, in another embodiment, prior to depositing the nanoparticles 20, an oxide layer (e.g., SiO₂) is deposited on the upper surface of the semiconductor layer 103, followed by etching of the oxide layer and the semiconductor layer by an appropriate method, such as reactive ion etching, to give the upper surface of the semiconductor layer a roughened structure.

Although the exemplary hot-carrier solar cells use specific materials, other materials, as those described in TW patent TWI812265B, may also be used in other embodiments. For example, the metal layer may be made of gold, silver, titanium, copper, chromium, nickel, or a combination thereof.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

What is claimed is:

1. A hot-carrier solar cell, comprising:
a semiconductor layer;
a metal layer comprising a plurality of continuous or discontinuous metal nano-islands in contact with an upper surface of the semiconductor layer;
a first electrode in contact with an upper surface of the metal layer; and
a second electrode in contact with a lower surface of the semiconductor layer;
wherein after being excited by incident photons, carriers in the metal layer form hot carriers that cross the interface between the metal layer and the semiconductor layer, thus generating a photocurrent;
wherein the hot-carrier solar cell is capable of absorbing incident light with wavelengths greater than a cutoff wavelength corresponding to the bandgap of the semiconductor layer, thereby achieving a conversion efficiency of over 6%.

2. The hot-carrier solar cell of claim 1, wherein the metal layer further comprises a plurality of metal particles above the plurality of metal nano-islands.

3. The hot-carrier solar cell of claim 1, wherein the upper surface of the semiconductor layer has an inverted pyramid structure array.

4. The hot-carrier solar cell of claim 1, wherein the upper surface of the semiconductor layer has a micro-structure array that confines light therein for resonance.

5. The hot-carrier solar cell of claim 1, wherein the first electrode is a finger-shaped electrode or mesh-shaped electrode on planes between adjacent inverted pyramid structures of the inverted pyramid structure array.

6. The hot-carrier solar cell of claim 2, wherein the average particle size of the plurality of metal particles is between 30 nm and 100 nm.

7. The hot-carrier solar cell of claim 2, wherein the spacing between the plurality of metal particles is between 0.2 nm and 5 nm.

8. The hot-carrier solar cell of claim 5, wherein a period of the inverted pyramid structure array is between 2 μm and 16 μm.

9. The hot-carrier solar cell of claim 2, wherein a thickness of the metal layer is between 8 nm and 18 nm.

10. The hot-carrier solar cell of claim 2, wherein the metal layer is formed by thermal evaporation, and the deposition rate of the thermal evaporation is between 0.6 Å/s and 1.2 Å/s.

11. The hot-carrier solar cell of claim 2, wherein the metal layer is made of gold, silver, titanium, copper, chromium, or nickel.

12. The hot-carrier solar cell of claim 1, wherein the absorption of the hot-carrier solar cell for incident light with a wavelength of 1300 nm reaches 70.44%.

13. The hot-carrier solar cell of claim 1, wherein the solar cell is annealed at a temperature between 35° C. and 200° C.

14. The hot-carrier solar cell of claim 5, wherein some patterns of the finger-shaped or mesh electrode are located above some inverted pyramid structures of the inverted pyramid structure array.

15. The hot-carrier solar cell of claim 2, wherein the plurality of metal particles have a predetermined morphology.

16. A method of manufacturing a hot-carrier solar cell, comprising:
providing a semiconductor layer;
depositing a plurality of nanoparticles on an upper surface of the semiconductor layer;
depositing a plurality of continuous or discontinuous metal nano-islands between the plurality of nanoparticles;
removing the plurality of nanoparticles, the plurality of metal nano-islands forming a metal layer;
depositing a first electrode on an upper surface of the metal layer; and
depositing a second electrode on a lower surface of the semiconductor layer.

17. The method of claim 16, further comprising:
annealing the metal layer to form a plurality of metal particles on the plurality of metal nano-islands, the plurality of metal nano-islands and the plurality of metal particles constituting the metal layer;

18. The method of claim 16, wherein before the step of depositing the plurality of nanoparticles, further comprising:
depositing an oxide layer on an upper surface of the semiconductor layer; and
etching the oxide layer and the semiconductor layer to give the upper surface of the semiconductor layer a roughened structure.
